(19) United States
(12) Patent Application Publication
(10) Pub. No.: US 2026/0090356 A1
(43) Pub. Date: Mar. 26, 2026

(54) SEMICONDUCTOR DEVICES

(71) Applicant: SAMSUNG ELECTRONICS CO., LTD., Suwon-si (KR)

(72) Inventors: Junsung Kim, Suwon-si (KR); Suhyun Bark, Suwon-si (KR); Jongmin Baek, Suwon-si (KR); Hoonseok Seo, Suwon-si (KR); Kangsub Yim, Suwon-si (KR)

(21) Appl. No.: 19/087,092

(22) Filed: Mar. 21, 2025

(30) Foreign Application Priority Data
Sep. 20, 2024 (KR) 10-2024-0127495

(51) Int. Cl. H01L 23/522; H01L 21/768; H01L 23/528; H01L 23/532

(52) U.S. Cl. CPC H10W 20/42; H10W 20/076; H10W 20/425; H10W 20/435; H10W 20/4421; H10W 20/47; H10W 20/082

(57) ABSTRACT

A semiconductor device includes a substrate having an active region; a first insulating layer disposed on the substrate; a second insulating layer disposed on the first insulating layer; a via contact disposed in the first insulating layer and electrically connected to the active region; an interconnection structure disposed in the second insulating layer and electrically connected to the via contact; and an etch stop layer disposed between the first insulating layer and the second insulating layer. The etch stop layer includes an upper layer region, a lower layer region and an intermediate film between the upper layer region and the lower layer region. Each of the upper layer region and the lower layer region includes a compound that includes a first element, and an intermediate film includes a second element intermixed with the first element.

### CROSS-REFERENCE TO RELATED APPLICATION(S)

This application claims benefit of priority under 35 U.S.C. § 11 to Korean Patent Application No. 10-2024-0127495 filed on Sep. 20, 2024, in the Korean Intellectual Property Office, the disclosure of which is incorporated herein by reference in its entirety.

### BACKGROUND

In various semiconductor devices such as a logic circuit and a memory, an interconnection structure in a vertical direction may be used between various conductive elements positioned on different levels, such as a conductive line in a back end of line (BEOL) or a contact plug connected to an active region such as a source and a drain.

Recently, as semiconductor elements have been highly integrated, a line width and/or a pitch may decrease or a path may become complex, such that the interconnection structures may cause an unwanted short between adjacent components, or as interconnection areas (or contact areas) may not be sufficiently ensured, which may increase contact resistance.

### SUMMARY

An example implementation of the present disclosure is to provide a semiconductor device having improved integration density and reliability.

According to an example implementation of the present disclosure, a semiconductor device includes a substrate having an active region; a first insulating layer disposed on the substrate; a second insulating layer disposed on the first insulating layer; a via contact disposed in the first insulating layer and electrically connected to the active region; an interconnection structure disposed in the second insulating layer and electrically connected to the via contact; and an etch stop layer disposed between the first insulating layer and the second insulating layer, and including an upper layer region and a lower layer region each including a compound including a first element, and an intermediate film including a second element intermixed with the first element between the upper layer region and the lower layer region.

According to an example implementation of the present disclosure, a semiconductor device includes a substrate having an active region; an interlayer insulating layer disposed on the substrate; a contact structure disposed in the interlayer insulating layer and electrically connected to the active region; a first insulating layer disposed on the interlayer insulating layer; a via contact disposed in the first insulating layer and electrically connected to the contact structure; a second insulating layer disposed on the first insulating layer; an interconnection line disposed in the second insulating layer and electrically connected to the via contact; and an etch stop layer disposed between the first insulating layer and the second insulating layer, and including an upper layer region and a lower layer region each including a compound including a first element, and an intermediate film including a second element intermixed with the first element between the upper layer region and the lower layer region.

According to an example implementation of the present disclosure, a semiconductor device includes a substrate having an active region a first insulating layer disposed on the substrate; a second insulating layer disposed on the first insulating layer; a via contact disposed in the first insulating layer and electrically connected to the active region; an interconnection structure disposed in the second insulating layer and electrically connected to the via contact; and an etch stop layer disposed between the first insulating layer and the second insulating layer, and including an upper layer region and a lower layer region each including a compound including aluminum, and an intermediate film including a silicon atomic layer between the upper layer region and the lower layer region, wherein the upper layer region has a thickness greater than a thickness of the lower layer region.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to example implementations of the present disclosure;

FIG. 2 is cross-sectional diagrams illustrating a semiconductor device taken along lines I1-I1′ and II1-II1′ according to example implementations of the present disclosure;

FIG. 3 is an enlarged diagram illustrating portion A1 illustrated in FIG. 2;

FIGS. 4A to 4C are cross-sectional diagrams illustrating a portion of processes of a method of manufacturing a semiconductor device according to an example implementation of the present disclosure;

FIGS. 5A to 5E are diagrams illustrating processes of forming a second etch stop layer according to an example implementation of the present disclosure;

FIGS. 6A and 6B are graphs illustrating results of secondary ion mass spectrometer (SIMS) and X-ray photoelectron spectroscopy (XPS) of a second etch stop layer according to an example implementation of the present disclosure;

FIGS. 7A to 7E are cross-sectional diagrams illustrating a portion of processes of a method of manufacturing a semiconductor device according to an example implementation of the present disclosure;

FIG. 8 is a plan diagram illustrating a semiconductor device according to example implementations of the present disclosure;

FIG. 9 is cross-sectional diagrams illustrating a semiconductor device taken along lines I2-I2′ and II2-II2′ according to example implementations of the present disclosure;

FIG. 10 is an enlarged diagram illustrating portion A2 illustrated in FIG. 9; and

FIGS. 11A to 11E are cross-sectional diagrams illustrating a portion of processes of a method of manufacturing a semiconductor device according to an example implementation of the present disclosure.

### DETAILED DESCRIPTION

Hereinafter, implementations of the present disclosure will be described as follows with reference to the accompanying drawings.

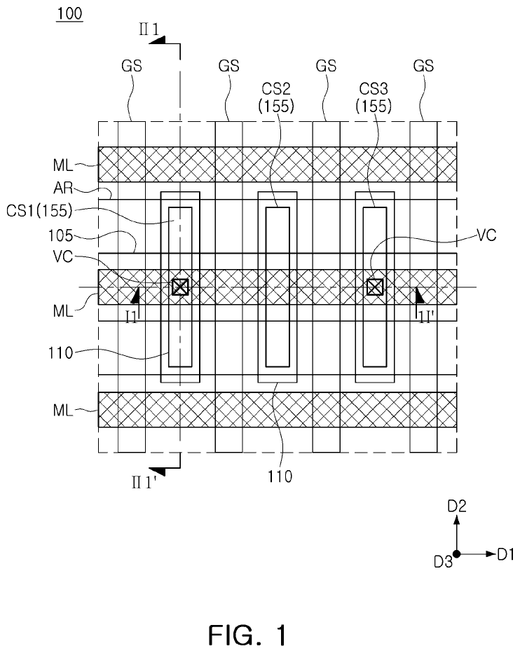

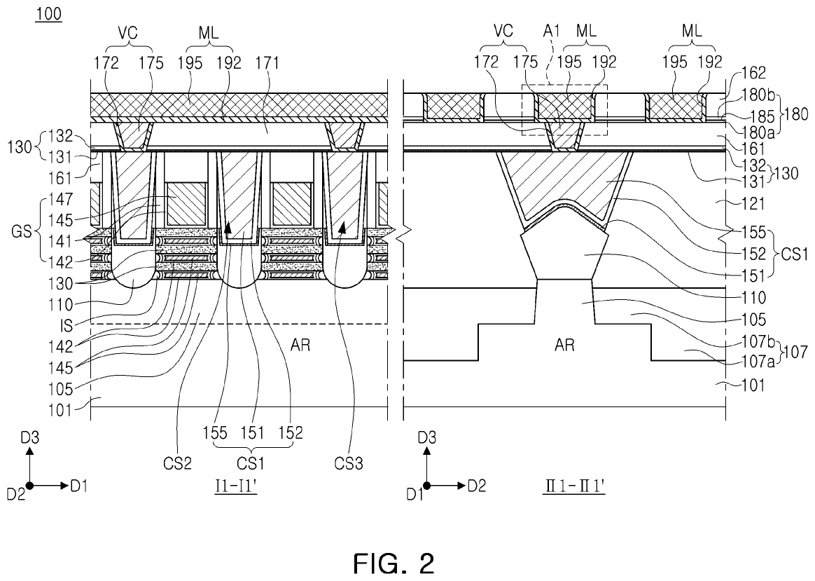

FIG. 1 is a plan diagram illustrating a semiconductor device according to example implementations. FIG. 2 is cross-sectional diagrams illustrating a semiconductor device taken along lines I1-I1′ and II1-II1′ according to example implementations.

Referring to FIGS. 1 and 2, a semiconductor device 100 according to the example implementation may include a substrate 101 having an active pattern 105, a plurality of channel patterns 130 stacked on the active pattern 105, a gate structure GS intersecting the active pattern 105 and surrounding the plurality of channel patterns 130, and source/drain patterns 110 connected to the channel patterns 130.

The substrate 101 may include a semiconductor, such as Si or Ge, or a compound semiconductor, such as SiGe, SiC, GaAs, InAs, or InP. In example implementations, the substrate 101 may have a silicon on insulator (SOI) structure. The active region AR may be a conductive region, such as a well doped with impurities or a structure doped with impurities. The active region AR may have a well structure of a specific conductivity-type. For example, the active region AR may have an N-type well for a PMOS transistor or a P-type well for an NMOS transistor. The active pattern 105 may protrude upwardly (e.g., D3) from an upper surface of the active region AR and may extend in the first direction (e.g., X-direction) on the active region AR.

The device isolation layer 107 may define the active region AR. The device isolation layer 107 may include an insulating material of silicon oxide or a silicon oxide series. The device isolation layer 107 may include a first isolation region 107a defining the active region AR and a second isolation region 107b defining the active pin 105. The first isolation region 107a may have a bottom surface deeper than the second isolation region 107b. For example, the first isolation region 107a may be referred to as deep trench isolation (DTI), and the second isolation region 107b may be referred to as shallow trench isolation (STI). The second isolation region 107b may be disposed on the active region AR. A portion of the active pattern 105 may protrude from the upper surface of the second isolation region 107b.

The channel patterns 130 may be stacked and spaced apart from each other in the vertical direction (e.g., D3) on the active pattern 105. Each of the channel patterns 130 may include a semiconductor material which may provide a channel region. For example, the channel patterns 130 may include at least one of silicon (Si), silicon germanium (SiGe), and germanium (Ge). The channel patterns 130 may be formed of, for example, the same material as a material of the substrate 101. The channel patterns 130 may have a width equal to or smaller than a width of the active pattern 105 in the second direction (e.g., D2) and a width equal to or similar to a width of the gate structure GS in the first direction (e.g., D1). In some example implementations, the channel patterns 130 may have a width smaller than a width of the gate structure GS such that side surfaces of the channel patterns 130 may be positioned below the gate structure GS in the first direction (e.g., D1). In the example implementation, the number of the channel patterns 130 is illustrated as three, but the number of the channel patterns 130 and the shape thereof may be varied.

The source/drain patterns 110 may be connected to both sides of each of the channel patterns 130. In the example implementation, the source/drain pattern 110 may be recessed into a partial region of the active pattern 105 on both sides of the gate structure GS and may be formed by selective epitaxial growth (SEG) in the recessed region. The source/drain pattern 110 may include Si, SiGe, or Ge, and depending on whether the transistor is an N-type or P-type transistor, the source/drain pattern 110 may have a different material or a different shape. For example, when being a PMOS transistor, the source/drain pattern 110 may include silicon-germanium (SiGe) and may be doped with P-type impurities (e.g., boron (B), indium (In), gallium (Ga)). The cross-section (e.g., D2)-D3) of the source/drain pattern 110 may be pentagonal. when being an NMOS transistor, the source/drain pattern 110 may include silicon and may be doped with N-type impurities (e.g., phosphorus (P), nitrogen (N), arsenic (As), antimony (Sb)). The cross-section (e.g., D2-D3) of the source/drain pattern 110 may be hexagonal or a polygon with a gentle angle.

As illustrated in FIG. 1, the gate structure GS may surround a plurality of channel patterns 130 and may extend in the second direction (e.g., D2). The gate structure GS may be arranged and spaced apart from each other at a regular interval in the first direction (e.g., D1). Specifically, the gate structure GS may be configured to surround each of the channel patterns 130. Channel regions of transistors may be formed in regions of the channel patterns 130 intersecting the gate structure GS. As described above, the semiconductor device 100 according to the example implementation may be provided as a gate-all-around type field effect transistor.

The gate structure GS may include a gate electrode 145, gate dielectric layers 142 between the gate electrode 145 and the channel patterns 130, and gate spacers 141 on side surfaces of the gate electrode 145. The gate structure GS may further include gate spacers 141 disposed on side surfaces of the gate electrode 145 and a gate capping layer 147 disposed on the gate electrode 145. The gate dielectric layers 142 may be disposed between the active pattern 105 and the gate electrode 145 and between the channel patterns 130 and the gate electrode 145. In some example implementations, the gate dielectric layers 142 may be disposed on the entirety of surfaces other than an uppermost surface of the gate electrode 145. For example, the gate dielectric layers 142 may extend between the gate electrode 145 and the gate spacers 141, but an example implementation thereof is not limited thereto. The gate dielectric layers 142 may include oxide, nitride, or a high-κ material. The high dielectric constant material may refer to a dielectric material having a dielectric constant higher than that of silicon oxide (SiO₂). The high-κ material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In some example implementations, the gate dielectric layers 142 may be formed as a multilayer film.

The gate spacers 141 may be disposed on both side surfaces of the gate electrode 145. The gate spacers 141 may insulate the source/drain patterns 110 and the gate electrode 145 from each other. In some example implementations, the gate spacers 141 may have a multilayer structure. The gate spacers 141 may be formed of oxide, nitride and oxynitride, and may be formed as low-κ films.

The internal spacers IS may be disposed on both side surfaces in the first direction (e.g., D1) of the gate electrode portions positioned between the channel patterns 130, respectively. The gate electrode 145 may be spaced apart from and electrically isolated from the source/drain patterns 110 by the internal spacers IS. The side surface of the internal spacers IS in contact with the gate electrode 145 may have a curved surface, but an example implementation thereof is not limited thereto. The internal spacers IS may include a low-κ material. For example, the internal spacers IS may include oxide, nitride and oxynitride.

The semiconductor device 100 according to the example implementation may have an interlayer insulating layer 121 disposed on the device isolation layer 107. The interlayer insulating layer 121 may be disposed around the gate structure GS. For example, the interlayer insulating layer 161 may include spin-on hardmask (SOH), flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide or combinations thereof. The interlayer insulating layer 121 may be formed using a chemical vapor deposition (CVD), a flowable-CVD process, or a spin coating process.

The first to third contact structures CS1, CS2, and CS3 employed in the example implementation may penetrate the interlayer insulating layer 121 and may be connected to the source/drain patterns 110, respectively. As illustrated in FIG. 2, the first to third contact structures CS1, CS2, and CS3 may include a conductive barrier 152 and a contact plug 155. The conductive barrier 152 may cover a side surface and a lower surface of the contact plug 155. A metal silicide layer 151 may be disposed between the conductive barrier 152 and the source/drain patterns 110. For example, the metal silicide layer 151 may include CoSi, NiSi, or TiSi. The conductive barrier 152 may include Ta, TaN, Mn, MnN, WN, Ti, or TiN. The contact plug 155 may include tungsten (W), cobalt (Co), titanium (Ti), an alloy thereof, or a combination thereof.

The semiconductor device 100 according to the example implementation may include an interconnection structure connected to first to third contact structures CS1 to CS3. The interconnection structure employed in the example implementation may include an interconnection line ML. Referring to FIGS. 1 and 2, the interconnection line ML according to the example implementation may include three interconnection lines ML each extending in the first direction (e.g., D1) and arranged in the second direction (e.g., D2), and the first and third contact structures CS1 and CS3 may be connected to the interconnection line ML by via contacts VC.

The first etch stop layer 130 may be included on the interlayer insulating layer 161, and in the example implementation, the first etch stop layer 130 may include an etch stop film 131 and an insulating protective film 132 stacked in order as a double layer. The etch stop film 131 may be used as an etch stop element for forming a via contact VC, and the insulating protective film 132 may be used as a barrier structure together with the etch stop film 131. In some example implementations, the etch stop film 131 may be a compound including an aluminum element. For example, the etch stop film 131 may include aluminum nitride (AlN), aluminum oxynitride (AlON), aluminum oxide (AlO), or aluminum oxycarbide (AlOC). For example, the insulating protective film 132 may include silicon nitride, silicon carbide, silicon oxynitride, or silicon carbonitride.

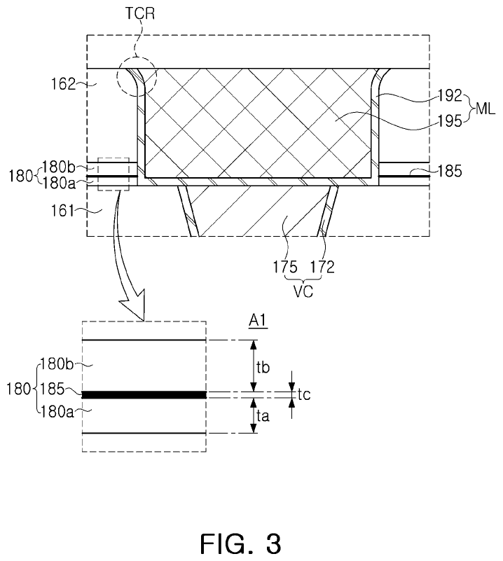

Referring to FIG. 2, a first insulating layer 161 and a second insulating layer 162 may be disposed in order on an interlayer insulating layer 121. A second etch stop layer 180 may be disposed between the first and second insulating layers 161 and 162. FIG. 3 is an enlarged diagram illustrating portion A1 illustrated in FIG. 2.

As illustrated in FIG. 3, the second etch stop layer 180 employed in the example implementation may include a single material system which is a compound including the first element, differently from the first etch stop layer 130, the second etch stop layer 180 may include an intermediate film 185 including the first element and the intermixed second element therebetween. The intermediate film 185 may divide the second etch stop layer 180 into an upper layer region 180b and a lower layer region 180a, and the upper layer region 180b and the lower layer region 180a may include the same material, that is, a compound including the first element.

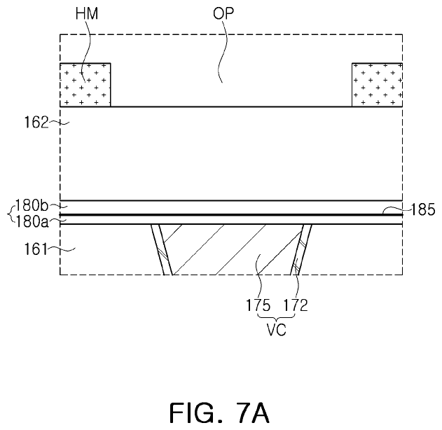

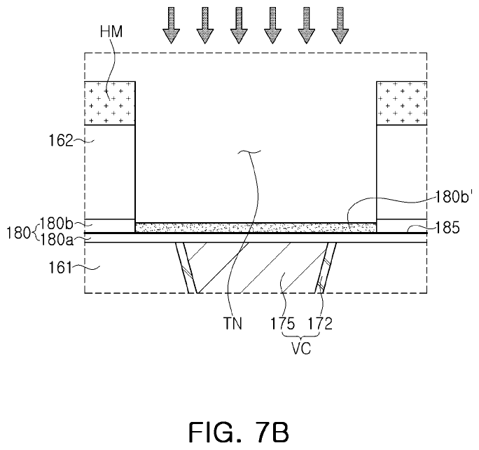

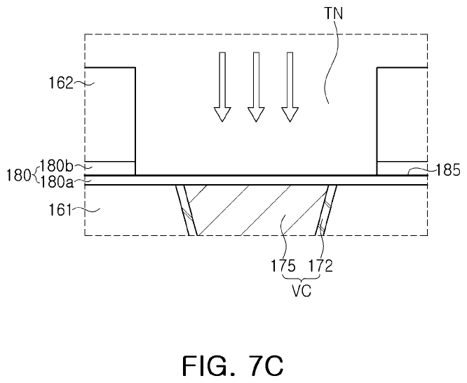

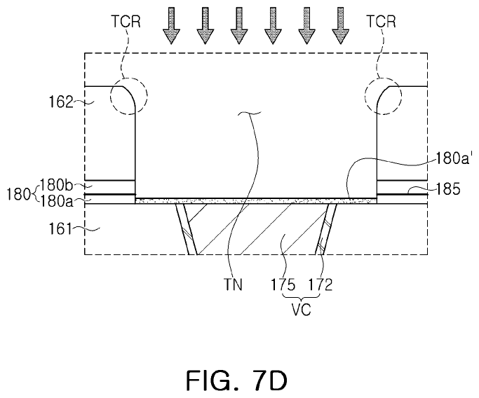

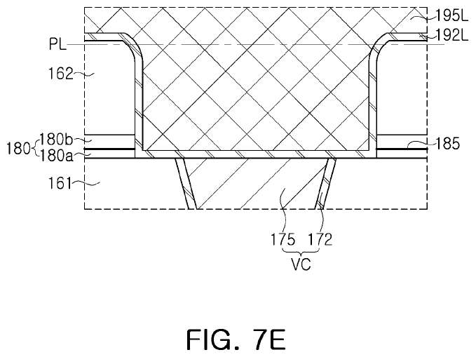

When the second etch stop layer 180 includes a single material system, damage such as pin-holes may occur during a process of forming a trench for the interconnection line ML (see FIG. 7B), and the etchant may melt the via contact VC through the pin-holes and the yield may be reduced during a process of stripping the hard mask used for forming the trench (see FIG. 7C). To prevent this, the second element may be intermixed in the intermediate region of the second etch stop layer 180, thereby forming an intermediate film 185 having high etchant resistance.

For example, the first element may include aluminum (Al), and the compound including the first element may include aluminum nitride (AlN), aluminum oxynitride (AlON), aluminum oxide (AlO), or aluminum oxycarbide (AlOC). Also, the second element may include silicon (Si), and the intermediate film 185 may include intermixed aluminum and silicon. In some example implementations, the intermediate film 185 may include an atomic layer formed of aluminum and intermixed silicon. However, an example implementation thereof is not limited thereto, and in some example implementations, at least one of the first and second elements may be a different element. For example, the second element may include titanium (Ti), hafnium (Hf), zirconium (Zr), or tantalum (Ta).

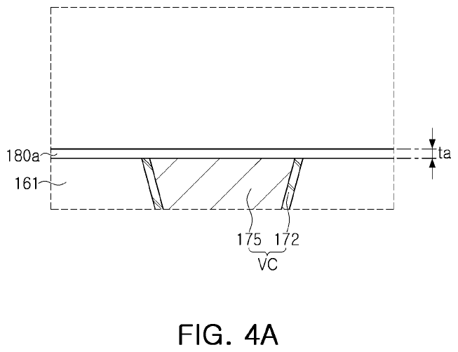

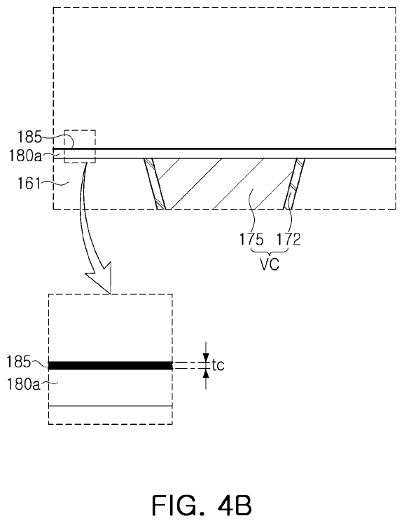

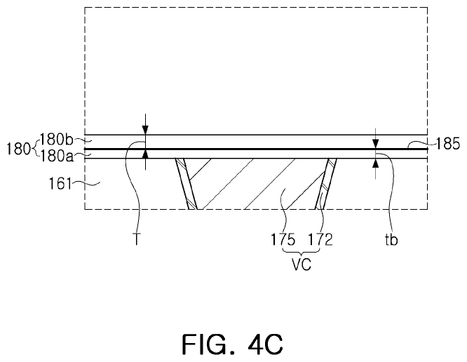

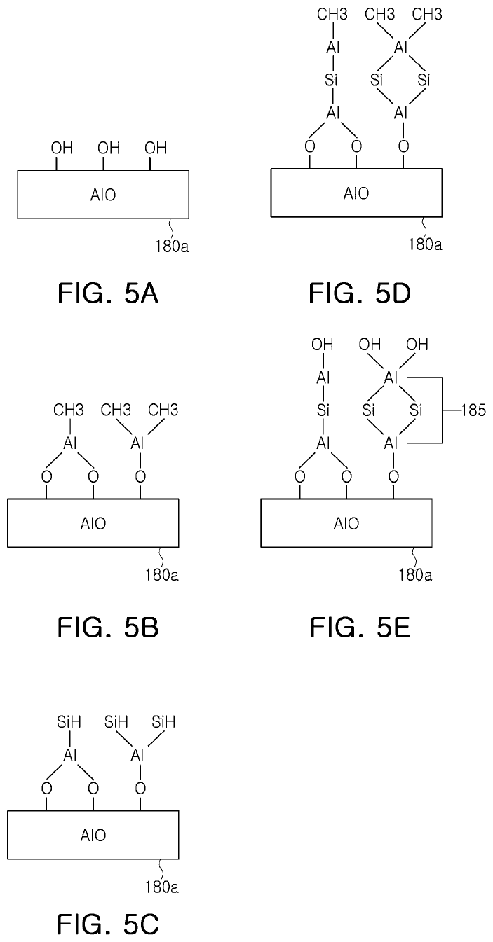

The second etch stop layer 180 employed in the example implementation may be formed by introducing an atomic layer including the second element intermixed with the first element into the intermediate film 185 using atomic layer deposition (ALD) during a process of growing a compound including the first element (see FIGS. 4A to 4C and FIG. 5). A detailed description thereof will be provided later.

For example, the thickness T of the second etch stop layer 180 may range from 20 Å to 50 Å. In the example implementation, a thickness tb of the upper layer region 180b may be greater than a thickness ta of the lower layer region 180a. For example, the thickness tb of the upper layer region 180b may be 15 Å to 40 Å, and the thickness ta of the lower layer region 180a may be 5 Å to 20 Å. A thickness tc of the intermediate film 185 may be 3 Å or less.

In the example implementation, an upper end region adjacent to the interconnection line ML of the second insulating layer 162 may have a rounded corner TCR. The rounded corner TCR may be formed during an etching process (see FIG. 7D) for removing the intermediate film 185.

The first and second insulating layers 161 and 162 may include the same or different materials. The first and second insulating layers 161 and 162 may include a material having a low dielectric constant (e.g., 3.3 or less). In some example implementations, at least one of the first and second insulating layers 161 and 162 may include a material the same as or similar to the interlayer insulating layer 121. For example, the first and second insulating layers 161 and 162 may include a fluorine-doped silicon oxide such as SiOF, a carbon-doped silicon oxide such as SiOC or SiOCH, a porous silicon oxide, an inorganic polymer such as hydrogen silsesquioxane (HSSQ), methyl silsesquioxane (MSSQ), or a spin-on organic polymer. For example, the first and second insulating layers 161 and 162 may be formed using chemical vapor deposition (CVD), a flowable-CVD process, or a spin coating process.

In the example implementation, the via contacts VC and the interconnection lines ML may be formed by a single damascene process, each formed in separate processes (see FIGS. 7A to 7E).

The via contact VC may include a conductive via 175 having a material the same as or similar to a material of the contact plug 155. For example, the conductive via 175 may include tungsten (W), molybdenum (Mo), cobalt (Co), or ruthenium (Ru). The via contact VC may include a conductive barrier 172 disposed on a side surface and a lower surface of the conductive via 175. For example, the conductive barrier 172 may include Ta, TaN, Mn, MnN, WN, Ti, or TiN.

The interconnection line ML may include a conductive line 195 and a conductive barrier 192 disposed on a side surface and a lower surface of the conductive line 195. The conductive barrier 192 may also be disposed between the conductive line 195 and the via contact VC. For example, the conductive line 195 may include copper (Cu). The conductive barrier 192 may include Ta, TaN, Mn, MnN, WN, Ti, or TiN.

In the example implementation, even when the second etch stop layer 180 includes a single material system which is a compound including the first element, by intermixing the second element with the first element in the intermediate region of the second etch stop layer 180 and forming an intermediate film 185 having high etchant resistance, pin-holes may be prevented in the second etch stop layer 180 (particularly, the lower layer region 180a) in the process of forming a trench (see FIG. 7B), and accordingly, yield of the via contact VC may be improved.

FIGS. 4A to 4C are cross-sectional diagrams illustrating a portion of processes (forming the second etch stop layer 180) of a method of manufacturing a semiconductor device according to an example implementation.

Referring to FIG. 4A, a partial region (or the lower layer region 180a) of the second etch stop layer 180 may be formed on the first insulating layer 161 on which the via contact VC is formed.

The lower layer region 180a of the second etch stop layer 180 may be formed by growing a compound including the first element. The growth process may be formed by an ALD process. The first element may include aluminum (Al), and the compound including the first element may include aluminum nitride (AlN), aluminum oxynitride (AlON), aluminum oxide (AlO), or aluminum oxide carbide (AlOC). In some example implementations, the lower layer region 180a of the second etch stop layer 180 may be formed by depositing aluminum oxide (AlO) using trimethylaluminum (TMA, Al(CH₃)₃) as an aluminum precursor. The lower layer region 180a may be formed with a thickness ta smaller than a thickness of the upper layer region (180b in FIG. 4C) to be subsequently grown. For example, a thickness ta of the lower layer region 180a may be 5 Å to 20 Å.

Thereafter, referring to FIG. 4B, an intermediate film 185 may be formed during the process of forming the second etch stop layer 180.

The intermediate film 185 including a second element intermixed with a first element may be formed on the lower layer region 180a using an ALD process.

Referring to FIGS. 5A to 5E, as an example of the process of forming the intermediate film 185, when the compound including the first element included in the lower layer region 180a is aluminum oxide (AlO), a process of forming a silicon atomic layer intermixed with aluminum using an ALD process as an intermediate film may be exemplified.

First, as illustrated in FIGS. 5A and 5B, the lower layer region 180a may be formed using an aluminum precursor such as trimethylaluminum (TMA). Thereafter, by supplying a silicon precursor instead of an aluminum precursor, a silicon atomic layer may be formed. As illustrated in FIG. 5C, the silicon atomic layer may be formed by supplying trisilylamine (TSA, (SiH₃)₃N) as a silicon precursor. Thereafter, as illustrated in FIG. 5D, the supply of trisilylamine may be stopped and trimethylaluminum may be supplied again, thereby forming an intermediate film 185 intermixed with silicon and aluminum.

As described above, the intermediate film 185 may include an atomic layer intermixed with aluminum. This intermixed intermediate film 185 may have higher chemical resistance with respect to a specific etchant (e.g., an etchant in a mask strip process) than chemical resistance of other regions of the second etch stop layer 180 (e.g., upper layer and lower layer regions). The intermediate film 185 may be provided with a relatively thin thickness at the atomic layer level. For example, the thickness tc of the intermediate film 185 may be 3 Å or less. The second element is not limited to silicon and may include other metal elements included in a ferroelectric compound. For example, the second element may include titanium (Ti), hafnium (Hf), zirconium (Zr), or tantalum (Ta).

Thereafter, referring to FIG. 4C, the second etch stop layer 180 having the intermediate film 185 may be formed by resuming growth of the second etch stop layer 180 on the intermediate film 185.

The upper layer region 180b may be formed on the intermediate film with a desired thickness using the same growth process as the lower layer region. In some example implementations (see FIG. 5D and FIG. 5E), the upper layer region 180b may be formed by forming aluminum oxide using an ALD process by supplying trimethylaluminum. As described above, a thickness tb of the upper layer region 180b may be greater than the thickness ta of the lower layer region 180a. The upper layer region 180a may actually act as an etch stop element when a trench for an interconnection line is formed. For example, the thickness tb of the upper layer region 180b may be in the range of 15 Å to 40 Å, and the total thickness T of the second etch stop layer 180 may be in the range of 20 Å to 50 Å.

Since the (second) etch stop layer according to the example implementation provides the intermediate film as an atomic layer, it may be difficult to accurately analyze the thickness of the intermediate film by a general analysis method. The presence of the intermediate film in the etch stop layer may be confirmed by analyzing the concentration of the second element in the intermediate film from the compound of the first element using a general atomic analysis method.

To confirm this, several analyses were performed by forming the second etch stop layer according to the example implementation. Specifically, similar to the process illustrated in FIGS. 5A to 5E, the etch stop layer may be formed of aluminum oxide using an ALD process using TMA as an Al precursor, the lower layer region may be formed with a thickness of about 10 Å, and a silicon atomic layer having a thickness of 1 atomic layer may be formed by TSA, a silane precursor, using an intermediate film. After the intermediate film is formed, the etch stop layer according to the example implementation may be formed by forming the upper layer region with a thickness of about 20 Å through the same growth process as the growth process of the lower layer region.

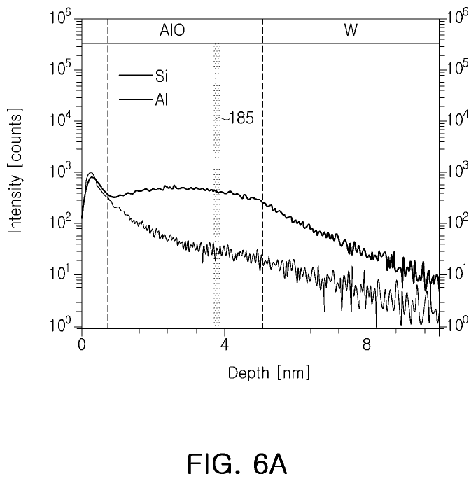

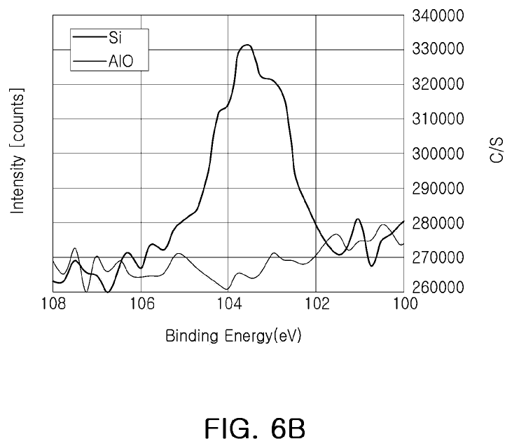

The secondary ion mass spectrometer (SIMS) and X-ray photoelectron spectroscopy (X-ray photoelectron spectroscopy, XPS) were performed on the etch stop layer according to the example implementation, and the results are represented in the graphs in FIGS. 6A and 6B, respectively.

Referring to FIGS. 6A and 6B, the concentration of silicon in the etch stop layer may be detected throughout the entire thickness due to the limitation of the analysis method (or equipment), and it may be difficult to limit the position of the silicon element to a specific region. However, as illustrated in FIG. 5E, a silicon atomic layer intermixed with aluminum (Al) may be present. This presence may be defined as the concentration of silicon in the entire region of the etch stop layer. For example, as confirmed in the results, the concentration of silicon in the etch stop layer may be one atomic percent to five atomic percent (1 at% to 5 at%). The concentration of silicon in the etch stop layer may be understood as having an intermediate film including the atomic silicon layer.

FIGS. 7A to 7E are cross-sectional diagrams illustrating a portion of processes of a method of manufacturing a semiconductor device according to an example implementation.

Referring to FIG. 7A, a second insulating layer 162 may be formed on a second etch stop layer 180, and a hard mask HM having an opening OP may be formed on the second insulating layer 162.

The second insulating layer 162 may include, for example, a fluorine-doped silicon oxide such as SiOF, a carbon-doped silicon oxide such as SiOC or SiOCH, a porous silicon oxide, an inorganic polymer, or a spin-on organic polymer. For example, the second insulating layer 162 may be formed using a chemical vapor deposition (CVD), a flowable-CVD process, or a spin coating process. The hard mask HM may include TiN and tungsten including carbon. The hard mask HM may have an opening OP defining an interconnection line. The opening OP may have a trench structure extending in one direction.

Thereafter, referring to FIG. 7B, a trench TN for an interconnection line may be formed in the second insulating layer 162 using a hard mask HM.

In this process, the second insulating layer 162 may be anisotropically etched. For example, this process may perform a dry etching process using a plasma atmosphere. For example, the second insulating layer 162 may be selectively anisotropically etched using a plasma atmosphere and a second etch stop layer. A fluorine-including gas, for example, a C₃F₈ gas or a C₄F₈ gas may be used as the etching gas. However, an example implementation thereof is not limited thereto, and may be varied. In some example implementations, the etching gas may further include an oxygen (O₂) gas and an argon AR gas. In this trench TN formation process, the upper layer region 180b of the etch stop layer may be used as an etch stop element, and as a result of the upper layer region reacting with the etching gas, which is an etchant, a reaction product 180b′ such as AlF₃ or Al0F may remain.

Thereafter, referring to FIG. 7C, a process of stripping the hard mask HM may be performed. The reaction product 180b′ may be removed during the stripping process or by a wet etching process.

When the hard mask HM is a TiN/tungsten compound, wet etching may be used, and a mixture of hydrogen peroxide (H₂O₂) (e.g., H₂O₂+H₂SO₄) may be used as an etchant for wet etching. Since the reaction product 180b′ in FIG. 7B includes defects such as pin-holes, in the case of a general single material system etch stop layer, the etchant may permeate through the pin-holes to the via contact VC and may damage the via contact VC, but in the example implementation, the etchant of the strip process may be blocked by the intermediate film 185 having a relatively high selectivity.

Thereafter, referring to FIG. 7D, the intermediate film 185 exposed to the trench TN may be removed.

Similarly to the process of forming the trench TN, this process may be performed as a dry etching process using a plasma atmosphere, and may be performed under conditions in which the etching rate may be controlled to be relatively low. Specifically, the etching process may be performed under conditions in which the upper end corner region TCR of the trench TN is rounded. During the etching process, the intermediate film 185 exposed to the trench TO may be removed, and the lower layer region 180a may react with the etchant, such that a reaction product 180a′ similar to the reaction product 180b′ in FIG. 7B may remain.

Thereafter, referring to FIG. 7E, after the reaction product 180a′ is removed, a conductive barrier layer 192L and a conductive material layer 195L for an interconnection line may be formed in the trench TO.

The reaction product 180a′ may be removed by a wet etching process. Since this wet etching process may be performed with a high selectivity with respect to the conductive material of the via contact VC, damage to the via contact VC may be reduced. The conductive barrier layer 192L may be conformally formed on an upper surface of the second insulating layer 162 and a sidewall and a bottom surface of the trench TO, and the conductive material layer 195L may be formed on the conductive barrier layer 192L to fill the trench T0. Thereafter, a desired interconnection line (“ML” in FIG. 3) may be formed by performing a process of planarizing the conductive barrier layer 192 and the conductive material layer 195 until the upper surface of the second insulating layer 162 is exposed (e.g., “PL” line). The planarization process may include, for example, a chemical mechanical polishing (CMP) process and/or an etch back process.

The process of forming the interconnection structure according to the example implementation is illustrated as being performed by a single damascene process. In some example implementations, the etch stop layer described above may also be advantageously used in a process of forming the interconnection structure by a dual damascene process. Also, the etch stop layer employed in the example implementation may also be advantageously used as an etch stop layer for interconnection structures of a semiconductor device having various structures.

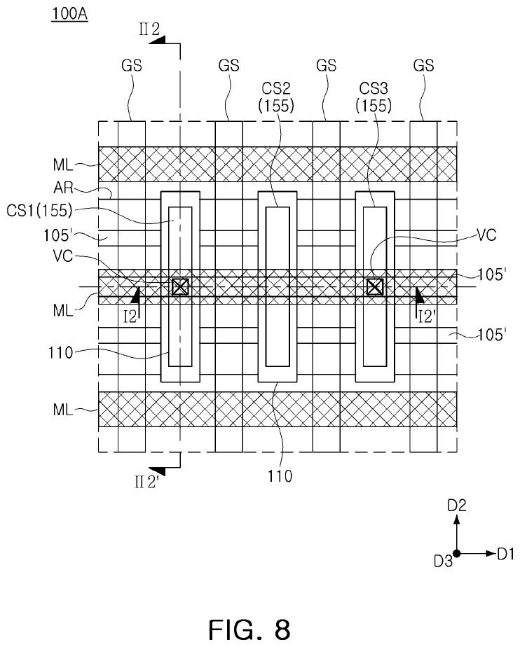

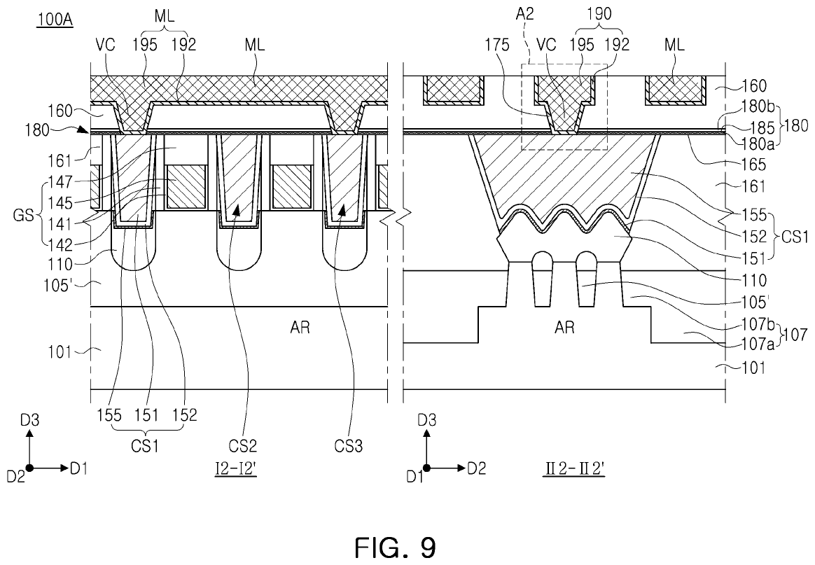

FIG. 8 is a plan diagram illustrating a semiconductor device according to example implementations. FIG. 9 is cross-sectional diagrams illustrating a semiconductor device taken along lines I2-I2′ and II2-II2′ according to example implementations.

Referring to FIGS. 8 and 9, the semiconductor device 100a according to the example implementation may be understood as being similar to the semiconductor device 100 illustrated in FIGS. 1 to 3, other than the configuration in which the channel region is provided with three active pins 105′, the configuration in which the interconnection structure 190 connected to the contact structures CS1 and CS3 has a structure formed by a dual damascene process, and the configuration in which the etch stop layer 180 according to the example implementation is disposed between the interlayer insulating layer 121 and the interconnection insulating layer 160. Also, the components in the example implementation may be understood by referring to the descriptions of the same or similar components of the semiconductor device 100 illustrated in FIGS. 1 to 3, unless otherwise indicated.

The channel region employed in the example implementation may include three active pins 105′, differently from the aforementioned example implementation. Each of the active pins 105′ may have a structure protruding upwardly (e.g., D3) from the upper surface of the substrate 101 and may extend in the first direction (e.g., D1). As illustrated in FIG. 8, the active pins 105′ may be arranged side by side in the second direction (e.g., D2) from the substrate 101. In the example implementation, three adjacently arranged active pins 105′ may provide a channel region for one transistor. In the example implementation, the number of active pins 105′ is illustrated as three, but an example implementation thereof is not limited thereto, and the number of active pins 105′ may be provided as one or multiple number (e.g., two).

The semiconductor device 100a according to the example implementation may include source/drain patterns 110 connected to both sides of three active pins 105′, respectively, and contact structures CS1, CS2, and CS3 connected to the source/drain patterns 110, respectively.

The semiconductor device 100a according to the example implementation may include a gate structure GS intersecting one region of the active pins 105′ and extending in the second direction (e.g., Y direction). The gate structure GS may include gate spacers 141, a gate dielectric layer 142, a gate electrode 145, and a gate capping layer 147, similarly to the aforementioned example implementation.

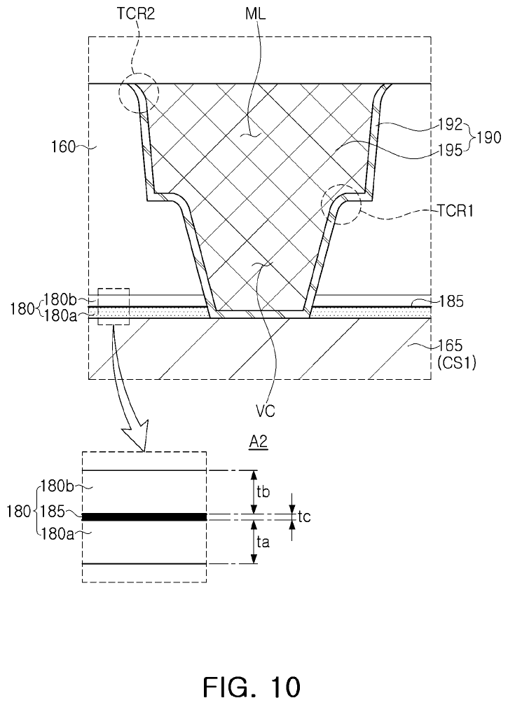

Referring to FIG. 9, an interconnection insulating layer 160 may be disposed on an interlayer insulating layer 121. An etch stop layer 180 may be disposed between the interlayer insulating layer 121 and the interconnection insulating layer 160. The interconnection insulating layer 160 may include the same or similar material as that of the first or second insulating layer 161 and 162 in the aforementioned example implementation. The interconnection structure 190 employed in the example implementation may have a structure in which the interconnection lines ML and the via contacts VC are integrated. As described above, the interconnection structure 190 may be formed by a dual damascene process. FIG. 10 is an enlarged diagram illustrating portion A2 illustrated in FIG. 9.

As illustrated in FIG. 10, the etch stop layer 180 employed in the example implementation may include an upper layer region 180b and a lower layer region 180a formed of the same material, and an intermediate film 185 between the upper layer region 180b and the lower layer region 180a.

The upper layer region 180b and the lower layer region 180a may include the same material which may be a compound including the first element, and the intermediate film 185 may include a second element intermixed with the first element. For example, the first element may include aluminum (Al), and the compound including the first element may include aluminum nitride (AlN), aluminum oxynitride (AlON), aluminum oxide (AlO), or aluminum oxycarbide (AlOC). Also, the second element may include silicon (Si), and the intermediate film 185 may include intermixed aluminum and silicon. In some example implementations, the intermediate film 185 may include an atomic layer of aluminum intermixed with silicon.

The etch stop layer 180 employed in the example implementation may be formed by introducing an atomic layer including a second element intermixed with the first element into the intermediate film 185 using an ALD process during the process of growing a compound including the first element (see FIGS. 4A to 4C and FIG. 5). The intermediate film 185 may be provided with an atomic layer thickness. For example, the thickness tc of the intermediate film 185 may be 3 Å or less. For example, the thickness T of the second etch stop layer 180 may be in a range of 20 Å to 50 Å. In the example implementation, the thickness tb of the upper layer region 180b may be similar to the thickness ta of the lower layer region 180a.

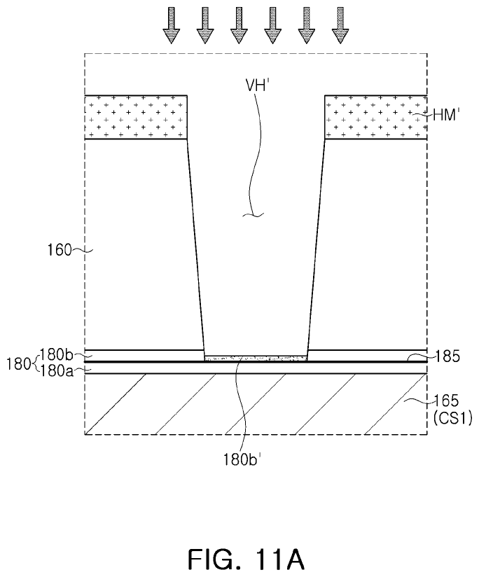

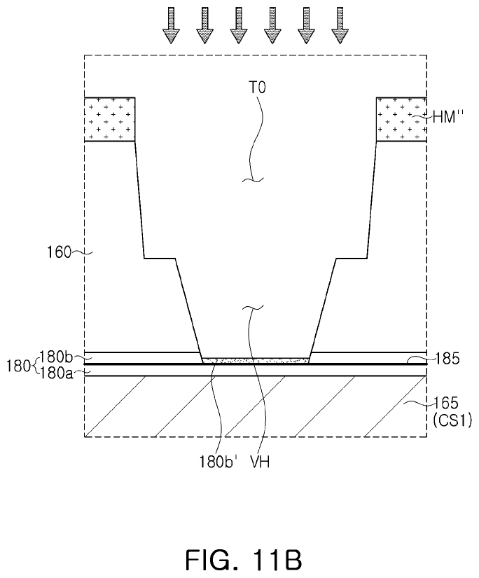

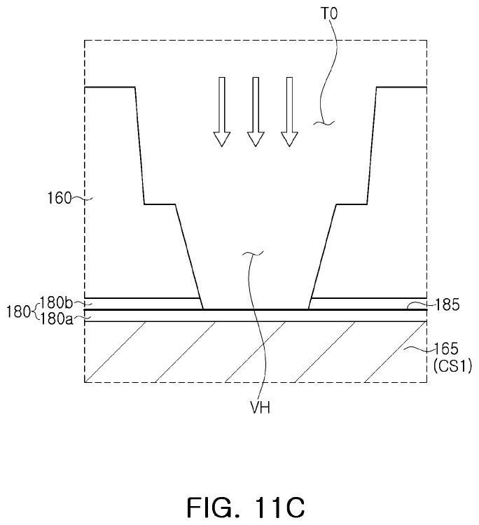

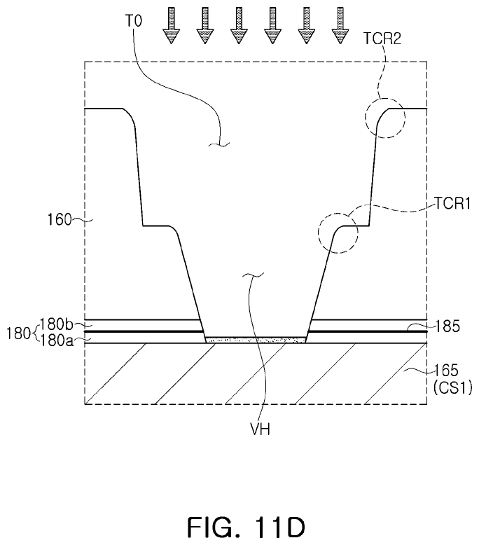

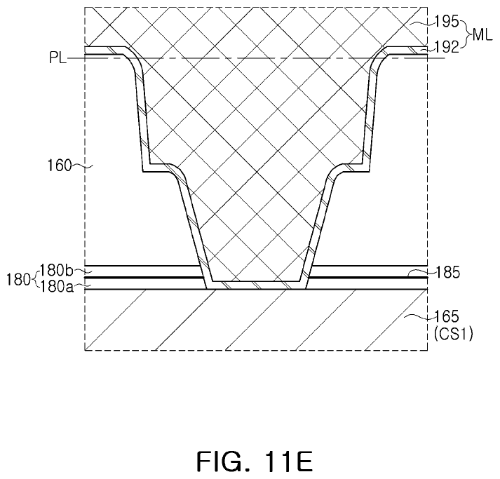

In the example implementation, the interconnection insulating layer 160 may have a rounded first upper end corner TCR1 adjacent to the via contact VC and a rounded second upper end corner TCR2 adjacent to the interconnection line ML. The first and second rounded corners TCR1 and TCR2 may be formed during an etching process for removing the intermediate film 185 (see FIG. 11D).

In the example implementation, the interconnection structure 190 may be formed by a dual damascene process in which the via contacts VC and the interconnection lines ML are formed simultaneously as described above (see FIGS. 11A to 11E). The interconnection structure 190 may include a conductive material 195 integrated with the via contact VC and the interconnection line ML, and a conductive barrier 192 disposed on a side surface and a lower surface of the conductive material 195. For example, the conductive material 195 may include Cu. For example, the conductive barrier 192 may include Ta, TaN, Mn, MnN, WN, Ti, or TiN.

Each of the contact structures CS1, CS2, and CS3 may include a conductive barrier 152 and a contact plug 155. The conductive barrier 152 may cover a side surface and a lower surface of the contact plug 155. A metal silicide layer 151 may be disposed between the conductive barrier 152 and the source/drain patterns 110. For example, the metal silicide layer 151 may include CoSi, NiSi, or TiSi. The conductive barrier 152 may include Ta, TaN, Mn, MnN, WN, Ti, or TiN. The contact plug 155 may include tungsten (W), cobalt (Co), titanium (Ti), an alloy thereof, or a combination thereof.

In the example implementation, even when the etch stop layer 180 includes a single material which is a compound including the first element, by forming an intermediate film 185 having high etchant resistance by intermixing the second element with the first element in the intermediate region of the etch stop layer 180, pin-holes may be prevented in the etch stop layer 180 (particularly, the lower layer region 180a) in the process of forming a trench (see FIGS. 11a and 11b), and accordingly, yield of the contact structures CS1 and CS3 may be improved.

FIGS. 11A to 11E are cross-sectional diagrams illustrating a portion of processes of a method of manufacturing a semiconductor device according to an example implementation.

Referring to FIG. 11A, a via hole VH′ may be formed using a first hard mask HM′ having a first opening OP1 on an interconnection insulating layer 160.

The interconnection insulating layer 160 may include, for example, a fluorine-doped silicon oxide such as SiOF, a carbon-doped silicon oxide such as SiOC or SiOCH, a porous silicon oxide, an inorganic polymer, or a spin-on organic polymer. The first opening OP1 may have a region overlapping the via contact VC illustrated in FIG. 8 in a planar view. The via hole VH′ may provide a space for the via contact. In some example implementations, the via hole VH′ may be formed to not reach the etch stop layer 180.

Thereafter, referring to FIG. 11B, a trench TO connected to the via hole VH may be formed using a second hard mask HM″ having a second opening OP2 on the interconnection insulating layer 160.

The second opening OP2 disposed in this process may have a region corresponding to the interconnection line ML in FIG. 8 and may extend in the first direction (e.g., D1) in a planar view. This process may use a new hard mask, or the hard mask HM′ used in the previous process may also be patterned and used as the hard mask HM″ for this process. In this process, the via hole VH′ formed in FIG. 11A may expand and may provide a via hole VH corresponding to the via contact VC.

A series of etching processes described in FIG. 11A and FIG. 11B may be performed by an anisotropic etching process. For example, this process may perform a dry etching process using a plasma atmosphere. For example, the interconnection insulating layer 160 may be selectively anisotropically etched using a plasma atmosphere and an etch stop layer 180, and an etching gas including fluorine may be used in this process. In a series of processes, the upper layer region 180b of the etch stop layer 180 may be used as an etch stop element, and as a result of the upper layer region reacting with the etching gas, which is an etchant, a reaction product 180b′ such as AlF₃ or Al0F may remain.

Thereafter, referring to FIG. 11C, a process of stripping the hard mask HM may be performed. The reaction product 180b′ may be removed during the stripping process or by a wet etching process.

When the hard mask HM″ is a TiN/tungsten compound, wet etching may be used, and a mixture of hydrogen peroxide (H₂O₂ (e.g., H₂O₂+H₂SO₄)) may be used as an etchant for wet etching. Since the reaction product 180b′ in FIG. 11B includes defects such as pin-holes, in the case of a general single material system etch stop layer, the etchant may penetrate through the pin-holes to the via contact VC and may damage the via contact VC, but in the example implementation, the etchant during the strip process may be blocked by the intermediate film 185 having a relatively high selectivity.

Thereafter, referring to FIG. 11D, the intermediate film 185 exposed to the trench TO may be removed.

Similarly to the process of forming a via hole VH′ and a trench TO, this process may include a dry etching process using a plasma atmosphere, and may be performed under conditions in which the etching rate is controlled to be relatively low. Specifically, the etching process may be performed under the condition that the upper end corner region TCR1 of the via hole VH and the upper end corner region TCR2 of the trench TO are rounded. During this etching process, the exposed intermediate film 185 may be removed, and the lower layer region 180a may react with the etchant, such that a reaction product 180a′ similar to the reaction product 180b′ in FIG. 11B may remain.

Thereafter, referring to FIG. 11E, after the reaction product 180a′ is removed, a conductive barrier layer 192L and a conductive material layer 195L may be formed in the via hole VH and the trench TO.

The reaction product 180a′ may be removed by a wet etching process. Since this wet etching process may be performed with a high selectivity with respect to the conductive material of the contact plug 155, damages to the contact plug 155 may be reduced. The conductive barrier layer 192L may be conformally formed on an upper surface of the second insulating layer 162 and sidewalls and bottom surfaces of the via hole VH and the trench TO, and the conductive material layer 195L may be formed on the conductive barrier layer 192L to fill the trench T0. Thereafter, a desired interconnection structure (“190” in FIG. 10) may be formed by performing a planarization process on the conductive barrier layer 192 and the conductive material layer 195 until the upper surface of the second insulating layer 162 is exposed (e.g., “PL” line). This planarization process may include, for example, a chemical mechanical polishing (CMP) and/or an etch back process.

According to the aforementioned example implementations, by intermixing specific elements in the etch stop layer of a single layer structure, damages to a lower metal, such as the contact plug, caused by the etchant may be effectively prevented during the process of forming metal interconnection.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device, comprising:
a substrate having an active region;
a first insulating layer on the substrate;
a second insulating layer on the first insulating layer;
a via contact in the first insulating layer and electrically connected to the active region;
an interconnection structure in the second insulating layer and electrically connected to the via contact; and
an etch stop layer between the first insulating layer and the second insulating layer, the etch stop layer including an upper layer region, a lower layer region, and an intermediate film between the upper layer region and the lower layer region, each of the upper layer region and the lower layer region including a compound that includes a first element, and the intermediate film including a second element intermixed with the first element.

2. The semiconductor device of claim 1, wherein the first element includes aluminum (Al), and the compound includes aluminum nitride (AlN), aluminum oxynitride (AlON), aluminum oxide (AlO), or aluminum oxycarbide (AlOC).

3. The semiconductor device of claim 2,
wherein the second element includes silicon (Si), and
wherein the intermediate film includes intermixed aluminum and silicon.

4. The semiconductor device of claim 3, wherein a concentration of silicon of the etch stop layer is one atomic percent to five atomic percent.

5. The semiconductor device of claim 3, wherein the intermediate film has a thickness of 3 Å or less.

6. The semiconductor device of claim 2, wherein the second element includes titanium (Ti), hafnium (Hf), zirconium (Zr), or tantalum (Ta).

7. The semiconductor device of claim 1, wherein a thickness of the upper layer region is greater than a thickness of the lower layer region.

8. The semiconductor device of claim 7, wherein the etch stop layer has a thickness ranging from 20 Å to 50 Å.

9. The semiconductor device of claim 7, wherein the thickness of the upper layer region is 15 Å to 40 Å, and the thickness of the lower layer region is 5 Å to 20 Å.

10. The semiconductor device of claim 1, wherein an upper end region of the second insulating layer adjacent to the interconnection structure has rounded corners.

11. The semiconductor device of claim 1, wherein the via contact includes tungsten (W), molybdenum (Mo), cobalt (Co) or ruthenium (Ru).

12. The semiconductor device of claim 1, wherein the interconnection structure includes copper (Cu).

13. The semiconductor device of claim 1, wherein at least one of the first or second insulating layers includes silicon oxide or carbon-doped silicon oxide, and the carbon-doped silicon oxide includes SiOC or SiCOH.

14. The semiconductor device of claim 1, wherein the interconnection structure includes a conductive barrier on surfaces in contact with the via contact and the second insulating layer.

15. The semiconductor device of claim 14, wherein the conductive barrier includes Ta, TaN, Mn, MnN, WN, Ti, or TiN.

16. A semiconductor device, comprising:
a substrate having an active region;
an interlayer insulating layer on the substrate;
a contact structure in the interlayer insulating layer and electrically connected to the active region;
a first insulating layer on the interlayer insulating layer;
a via contact in the first insulating layer and electrically connected to the contact structure;
a second insulating layer on the first insulating layer;
an interconnection line in the second insulating layer and electrically connected to the via contact; and
an etch stop layer between the first insulating layer and the second insulating layer, the etch stop layer including an upper layer region, a lower layer region and an intermediate film between the upper layer region and the lower layer region, each of the upper layer region and the lower layer region including a compound that includes a first element, and the intermediate film including a second element intermixed with the first element.

17. The semiconductor device of claim 16,
wherein the first element includes aluminum (Al), and each of the upper layer region and the lower layer region includes aluminum nitride (AlN), aluminum oxynitride (AlON), aluminum oxide (AlO), or aluminum oxide carbide (AlOC), and
wherein the second element includes silicon, and the intermediate film includes a silicon atomic layer intermixed with aluminum.

18. The semiconductor device of claim 16, wherein the interconnection line includes a conductive barrier on surfaces in contact with the via contact and the second insulating layer.

19. The semiconductor device of claim 16, wherein the via contact includes tungsten (W), molybdenum (Mo), cobalt (Co), or ruthenium (Ru), and the interconnection line includes copper (Cu).

20. A semiconductor device, comprising:
a substrate having an active region
a first insulating layer on the substrate;
a second insulating layer on the first insulating layer;
a via contact in the first insulating layer and electrically connected to the active region;
an interconnection structure in the second insulating layer and electrically connected to the via contact; and
an etch stop layer between the first insulating layer and the second insulating layer, the etch stop layer including an upper layer region, a lower layer region and an intermediate film between the upper layer region and the lower layer region, each of the upper layer region and the lower layer region including a compound that includes aluminum, and the intermediate film including a silicon atomic layer,
wherein the upper layer region has a thickness greater than a thickness of the lower layer region.
